(19) United States
(12) Patent Application Publication
(10) Pub. No.: US 2023/0411126 A1
(43) Pub. Date: Dec. 21, 2023

(54) CHAMBER INSULATION PLATE AND SUBSTRATE PROCESSING APPARATUS INCLUDING THE SAME

(71) Applicant: SEMES CO., LTD., Cheonan-si (KR)

(72) Inventor: Dongmok LEE, Cheonan-si (KR)

(21) Appl. No.: 18/200,017

(22) Filed: May 22, 2023

(30) Foreign Application Priority Data
Jun. 15, 2022 (KR) 10-2022-0072538

(51) Int. Cl. H01J 37/32; H01L 21/683

(52) U.S. Cl. CPC H01J 37/32715; H01L 21/6833; H01J 2237/334; H01J 2237/2007; H01J 2237/038

(57) ABSTRACT

Provided is a substrate processing apparatus including a chamber having a processing space for processing a substrate with plasma, a substrate support for supporting the substrate in the chamber, and an insulation plate disposed under the substrate support to electrically insulate the substrate support from the chamber, wherein the insulation plate includes a base material body made of a ceramic material having a first dielectric constant, and a dielectric constant controller dispersed in the base material body and having a second dielectric constant different from the first dielectric constant to prevent loss of radio-frequency (RF) bias power applied to the substrate support to control ion energy in the plasma.

### CROSS-REFERENCE TO RELATED PATENT APPLICATION

This application claims the benefit of priority under 35 U.S.C. § 119 to Korean Patent Application No. 10-2022-0072538, filed on Jun. 15, 2022, in the Korean Intellectual Property Office, the disclosure of which is incorporated herein in its entirety by reference.

### BACKGROUND

### 1. Field of the Invention

The present invention relates to a chamber insulation plate and a substrate processing apparatus including the same.

### 2. Description of the Related Art

Implementation of an etching process having a high etch rate for a material layer on a substrate is typically needed to manufacture electronic devices such as semiconductor devices and display devices. In a substrate processing apparatus for performing a dry etching process, when radio-frequency (RF) power applied to generate plasma is lost, an etch rate is reduced.

A related technology is disclosed in Korean Patent Publication No. 10-2007-0062102A.

### SUMMARY

The example embodiments provide a chamber insulation plate capable of implementing an etching process having a high etch rate and of improving etch uniformity on a substrate, and a substrate processing apparatus including the same.

However, the scope of the present invention is not limited thereto.

According to an aspect of the present invention, there is provided a chamber insulation plate to be disposed under a substrate support for supporting a substrate in a plasma processing chamber, the plasma processing chamber configured to electrically insulate the substrate support from the chamber, the chamber insulation plate including a base material body made of a ceramic material having a first dielectric constant, and a dielectric constant controller dispersed in the base material body and having a second dielectric constant different from the first dielectric constant to reduce loss of radio-frequency (RF) bias power when applied to the substrate support to control ion energy in the plasma.

The dielectric constant controller may include pores.

The chamber insulation plate may have a porosity of 2% to 20%.

The ceramic material having the first dielectric constant may include at least one of aluminum nitride (AlN), silicon carbide (SiC), yttria (Y₂O₃), sapphire, yttrium oxyfluoride (YOF), and alumina (Al₂O₃).

The dielectric constant controller may include particles having the second dielectric constant, wherein the second dielectric constant is lower than the first dielectric constant.

The chamber insulation plate is a substrate insulation plate.

A combination comprising a chamber insulation plate and a substrate support, wherein the chamber insulation plate is a substrate insulation plate in contact with the substrate support, and wherein the chamber insulation plate is disposed under the substrate support for supporting a substrate in a plasma processing chamber, the plasma processing chamber configured to electrically insulate the substrate support from the chamber, the chamber insulation plate including a base material body made of a ceramic material having a first dielectric constant, and a dielectric constant controller dispersed in the base material body and having a second dielectric constant different from the first dielectric constant to reduce loss of radio-frequency (RF) bias power when applied to the substrate support to control ion energy in the plasma.

A combination comprising a chamber insulation plate, a substrate support, and a base plate comprised of metal, wherein chamber insulation part is a substrate base plate that is interposed between the substrate support and the base plate to form a capacitor, wherein the dielectric constant controller reduces a capacitance of the capacitor, and wherein the chamber insulation plate is disposed under the substrate support for supporting a substrate in a plasma processing chamber, the plasma processing chamber configured to electrically insulate the substrate support from the chamber, the chamber insulation plate including a base material body made of a ceramic material having a first dielectric constant, and a dielectric constant controller dispersed in the base material body and having a second dielectric constant different from the first dielectric constant to reduce loss of radio-frequency (RF) bias power when applied to the substrate support to control ion energy in the plasma.

According to another aspect of the present invention, there is provided a substrate processing apparatus including a chamber having a processing space for processing a substrate with plasma, a substrate support for supporting the substrate in the chamber, and an insulation plate disposed under the substrate support to electrically insulate the substrate support from the chamber, wherein the insulation plate includes a base material body made of a ceramic material having a first dielectric constant, and a dielectric constant controller dispersed in the base material body and having a second dielectric constant lower than the first dielectric constant to reduce loss of radio-frequency (RF) bias power applied to the substrate support to control ion energy in the plasma.

The substrate support may include a dielectric plate for placing the substrate thereon, and an electrode plate disposed under the dielectric plate, and the insulation plate may be disposed in contact with a bottom surface of the electrode plate to reduce loss of the RF bias power applied to the electrode plate.

The ceramic material having the first dielectric constant may include at least one of aluminum nitride (AlN), silicon carbide (SiC), yttria (Y₂O₃), sapphire, yttrium oxyfluoride (YOF), and alumina (Al₂O₃).

The dielectric constant controller having the second dielectric constant may include pores.

A porosity in a central region of the insulation plate corresponding to a central portion of the substrate may be different from a porosity in an edge region of the insulation plate corresponding to an edge portion of the substrate.

The porosity in the central region of the insulation plate may be lower than the porosity in the edge region of the insulation plate.

The porosity in the central region of the insulation plate may be higher than the porosity in the edge region of the insulation plate.

The insulation plate may have a laminated structure having different porosities, and a porosity in an upper layer and a lower layer of the insulation plate may be different from a porosity in a middle layer interposed between the upper and lower layers.

The porosity in the upper and lower layers may be lower than the porosity in the middle layer.

The porosity in the upper and lower layers may be higher than the porosity in the middle layer.

The dielectric constant controller having the second dielectric constant may include particles having the second dielectric constant.

The particles having the second dielectric constant may include at least one of aluminum nitride (AlN), silicon carbide (SiC), yttria (Y₂O₃), sapphire, yttrium oxyfluoride (YOF), and alumina (Al₂O₃).

The insulation plate may include a central region corresponding to a central portion of the substrate, and an edge region corresponding to an edge portion of the substrate, and a dispersion density of the particles having the second dielectric constant in the central region may be different from a dispersion density of the particles having the second dielectric constant in the edge region.

The insulation plate may have a laminated structure having different dispersion densities of the particles having the second dielectric constant, and a dispersion density of the particles having the second dielectric constant in an upper layer and a lower layer of the insulation plate may be different from a dispersion density of the particles having the second dielectric constant in a middle layer interposed between the upper and lower layers.

According to another aspect of the present invention, there is provided a substrate processing apparatus including a chamber having a processing space for processing a substrate with plasma, a substrate support for supporting the substrate in the chamber, and an insulation plate disposed under the substrate support to electrically insulate the substrate support from the chamber, wherein the insulation plate includes a base material body made of a ceramic material having a first dielectric constant, and pores dispersed in the base material body to reduce loss of radio-frequency (RF) bias power applied to the substrate support to control ion energy in the plasma, wherein the ceramic material having the first dielectric constant includes at least one of aluminum nitride (AlN), silicon carbide (SiC), yttria (Y₂O₃), sapphire, yttrium oxyfluoride (YOF), and alumina (Al₂O₃), and wherein the insulation plate has a porosity of 2% to 20%.

### BRIEF DESCRIPTION OF THE DRAWINGS

The above and other features and advantages will become more apparent by describing in detail embodiments thereof with reference to the attached drawings in which like reference numerals refer to like elements throughout. In the drawings:

FIG. 1 is a cross-sectional view of a substrate processing apparatus according to an example embodiment;

FIG. 2 is a perspective view of an insulation plate of a substrate processing apparatus, according to example embodiments;

FIGS. 3 to 8 are cross-sectional views of the insulation plate taken along line A-A′ of FIG. 2, according to various example embodiments;

FIG. 9 is a perspective view of an insulation plate of a substrate processing apparatus, according to other example embodiments;

FIGS. 10 to 15 are cross-sectional views of the insulation plate taken along line A-A′ of FIG. 9, according to various example embodiments;

FIG. 16 is a graph showing an etch rate based on a reactance of an insulation plate in a substrate processing apparatus, according to example embodiments; and

FIG. 17 is an example method of manufacturing a semiconductor device according to an example embodiment.

### DETAILED DESCRIPTION

Hereinafter, example embodiments will be described in detail with reference to the attached drawings.

The invention may, however, be embodied in many different forms and should not be construed as being limited to the example embodiments set forth herein; rather, these example embodiments are provided so that this disclosure will be thorough and complete, and will fully convey the concepts of the invention to one of ordinary skill in the art. In the drawings, the thicknesses or sizes of layers are exaggerated for clarity or convenience of explanation.

Example embodiments of the invention are described herein with reference to schematic illustrations of idealized embodiments (and intermediate structures). As such, variations from the shapes of the illustrations as a result, for example, of manufacturing techniques and/or tolerances, are to be expected. Thus, the example embodiments should not be construed as limited to the particular shapes of regions illustrated herein, but are to include deviations in shapes that result, for example, from manufacturing.

It will be understood that, although the terms “first,” “second,” “third,” etc. may be used herein to describe various elements, components, regions, layers and/or sections, these elements, components, regions, layers and/or sections should not be limited by these terms. Unless the context indicates otherwise, these terms are only used to distinguish one element, component, region, layer or section from another element, component, region, layer or section, for example as a naming convention. Thus, a first element, component, region, layer or section discussed below in one section of the specification could be termed a second element, component, region, layer or section in another section of the specification or in the claims without departing from the teachings of the present invention. In addition, in certain cases, even if a term is not described using “first,” “second,” etc., in the specification, it may still be referred to as “first” or “second” in a claim in order to distinguish different claimed elements from each other.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

It will be further understood that the terms “comprises” and/or “comprising” and “includes” and/or “including,” when used in this specification to describe compositions of various materials, specify that the materials may be formed predominantly of that material or solely of that material, unless the context indicates otherwise.

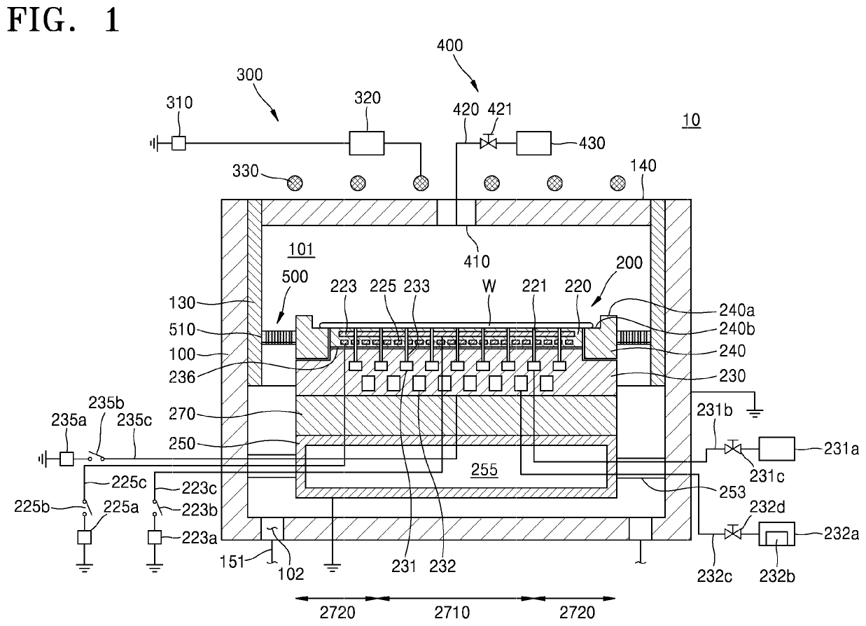

FIG. 1 is a cross-sectional view of a substrate processing apparatus 10 according to an example embodiment. The illustrated substrate processing apparatus 10 is a plasma processing apparatus (e.g., an inductively coupled plasma (ICP) processing apparatus). The substrate processing apparatus 10 processes a substrate W by using plasma.

A semiconductor wafer is provided as an example of the substrate W. The substrate W processed by the substrate processing apparatus 10 according to the example embodiments is not limited to the wafer and may be, for example, a large substrate for flat panel displays or a substrate for electroluminescent (EL) devices or solar cells. Meanwhile, the substrate processing apparatus 10 may perform an etching process on the substrate W. The following description will be focused on the etching process but may also be applied to a substrate processing apparatus for performing a deposition process.

The substrate processing apparatus 10 may include a process chamber 100, a substrate support 200, a plasma unit 300, and an insulation plate 270, and further may include a gas supply unit 400 and a baffle unit 500.

The process chamber 100 provides therein a processing space 101 where the substrate W is processed. The processing space 101 may be maintained at a process pressure lower than the atmospheric pressure and provided as a sealed space. The process chamber 100 may be made of a metal. For example, the process chamber 100 may be made of aluminum (Al). The surface of the process chamber 100 may be anodized. The process chamber 100 may be electrically grounded. Vent holes 102 may be provided in a bottom surface of the process chamber 100. The vent holes 102 may be connected to vent lines 151. Reaction byproducts produced while processing the substrate W and gases staying in an inner space of the process chamber 100 may be expelled to the outside through the vent lines 151. Due to the expulsion, the inside of the process chamber 100 may be reduced to a certain pressure.

According to an example, a liner 130 may be provided in the process chamber 100. The liner 130 may have a cylindrical shape having an open top and bottom. The liner 130 may be provided to be in contact with an inner surface of the process chamber 100. The liner 130 may protect and prevent an inner wall of the process chamber 100 from being damaged by arc discharge. The liner 130 may also prevent impurities produced while processing the substrate W from being deposited on the inner wall of the process chamber 100. Optionally, the liner 130 may not be provided. The liner 130 may be exposed to the processing space 101 in the process chamber 100 to react with a first cleaning gas, and may include yttria (Y₂O₃).

A window 140 is provided on the process chamber 100. The window 140 is provided in a plate shape. The window 140 covers the open top of the process chamber 100 to seal the processing space 101. The window 140 may include a dielectric substance.

The substrate support 200 is provided in the process chamber 100. In an embodiment, the substrate support 200 may be spaced upward from the bottom surface of the process chamber 100 by a certain distance in the process chamber 100. The substrate support 200 may support the substrate W. The substrate support 200 include an electrostatic chuck (ESC) including an electrostatic electrode 223 for adsorbing the substrate W by using an electrostatic force. In other embodiments, the substrate support 200 may support the substrate W in various manners, e.g., mechanical clamping. The substrate support 200 including the ESC will now be described as an example.

The substrate support 200 may include a dielectric plate 220 and an electrode plate 230.

The dielectric plate 220 and the electrode plate 230 may form the ESC. The dielectric plate 220 may support the substrate W. The circumference of the dielectric plate 220 may be surrounded by a focus ring 240. The dielectric plate 220 may be positioned on top of the electrode plate 230. The dielectric plate 220 may be provided as a disk-shaped dielectric substance. The substrate W may be placed on a top surface of the dielectric plate 220. The top surface of the dielectric plate 220 may have a radius less than that of the substrate W. Accordingly, an edge region of the substrate W may be positioned outside the dielectric plate 220. The edge of the substrate W may be placed on a top surface of the focus ring 240.

The dielectric plate 220 may include the electrostatic electrode 223, a heater 225, and first supply channels 221 therein. The first supply channels 221 may penetrate from the top surface to a bottom surface of the dielectric plate 220. The first supply channels 221 may penetrate the top surface of the electrode plate 230 and may extend into the electrode plate 230. A plurality of first supply channels 221 may be spaced apart from each other and provided as passages through which a heat transfer medium is supplied to a bottom surface of the substrate W.

The electrostatic electrode 223 may be electrically connected to a first power source 223a through a first power line 223c. The first power source 223a may include a direct current (DC) power source. A switch 223b may be mounted between the electrostatic electrode 223 and the first power source 223a. The electrostatic electrode 223 may be electrically connected to or disconnected from the first power source 223a by turning on or off the switch 223b. When the switch 223b is turned on, a DC current may be applied to the electrostatic electrode 223 through the first power line 223c. An electrostatic force may be generated between the electrostatic electrode 223 and the substrate W by the current applied to the electrostatic electrode 223, and the substrate W may be adsorbed onto the dielectric plate 220 by the electrostatic force. When the switch 223b is turned off, a DC current may not be applied to the electrostatic electrode 223.

The heater 225 may be positioned under the electrostatic electrode 223. The heater 225 may be electrically connected to a second power source 225a through second power line 225c. When the switch 225b is turned on, a current may be applied to the heater 225 through the second power line 225c. The heater 225 may generate heat by resisting the current applied from the second power source 225a through the second power line 225c. The generated heat may be transferred to the substrate W through the dielectric plate 220. The substrate W may be maintained at a certain temperature by the heat generated by the heater 225. The heater 225 may include a spiral coil.

The electrode plate 230 may be positioned under the dielectric plate 220. The bottom surface of the dielectric plate 220 may be bonded to a top surface of the electrode plate 230 by an adhesive 236. The electrode plate 230 may be made of a metal such as Al. The top surface of the electrode plate 230 may be stepped in such a manner that a central region is higher than an edge region thereof. The central region of the top surface of the electrode plate 230 may have an area corresponding to and be bonded to the bottom surface of the dielectric plate 220. The electrode plate 230 may provide a first circulation channel 231, a second circulation channel 232, and second supply channels 233 therein.

The first circulation channel 231 may be provided as a passage through which a heat transfer medium circulates. The first circulation channel 231 may be provided in a spiral shape in the electrode plate 230. Alternatively, the first circulation channel 231 may be provided as a plurality of ring-shaped channels having different radii and the same center. The first circulation channels 231 may be connected to each other. The first circulation channels 231 may be provided at the same height.

The second circulation channel 232 may be provided as a passage through which a coolant circulates. The second circulation channel 232 may be provided in a spiral shape in the electrode plate 230. Alternatively, the second circulation channel 232 may be provided as a plurality of ring-shaped channels having different radii and the same center. The second circulation channels 232 may be connected to each other. The second circulation channels 232 may have a cross-sectional area greater than that of the first circulation channels 231. The second circulation channels 232 may be provided at the same height. The second circulation channels 232 may be provided under the first circulation channels 231. For example, the second circulation channels 232 may be provided within the electrode plate 230 at a lower height than the first circulation channels 231.

The second supply channels 233 may extend upward from the first circulation channel 231 to the top surface of the electrode plate 230. The second supply channels 233 may be provided to correspond to the number of first supply channels 221 and may connect the first circulation channel 231 to the first supply channels 221.

The first circulation channel 231 may be connected to a heat transfer medium reservoir 231a through a heat transfer medium supply line 231b. The heat transfer medium reservoir 231a may store a heat transfer medium. The heat transfer medium may include an inert gas. According to an embodiment, the heat transfer medium may include a helium (He) gas. The He gas may be supplied to the first circulation channel 231 through the heat transfer medium supply line 231b and then be supplied to the bottom surface of the substrate W sequentially through the second supply channels 233 and the first supply channels 221. A valve 231c may be mounted on the heat transfer medium supply line 231b. The valve 231c may open or close the heat transfer medium supply line 231b to control a flow rate of the He gas supplied through the heat transfer medium supply line 231b. The He gas may serve as a medium through which heat transferred from the plasma to the substrate W is transferred to the dielectric plate 220.

The second circulation channel 232 may be connected to a coolant reservoir 232a through a coolant supply line 232c. The coolant reservoir 232a may store a coolant. A cooler 232b may be provided in the coolant reservoir 232a. The cooler 232b may cool the coolant to a certain temperature. In other embodiments, the cooler 232b may be mounted on the coolant supply line 232c. The coolant supplied to the second circulation channel 232 through the coolant supply line 232c may circulate along the second circulation channel 232 and cool the electrode plate 230. A valve 232d may be mounted on the coolant supply line 232c. The valve 232d may open or close the coolant supply line 232c to control a flow rate of the coolant supplied through the coolant supply line 232c. When the electrode plate 230 is cooled, the dielectric plate 220 and the substrate W may also be cooled to maintain the substrate W at a certain temperature.

The electrode plate 230 may include a metal plate. According to an example, the entirety of the electrode plate 230 may be provided as a metal plate. The electrode plate 230 may be electrically connected to a third power source 235a. The third power source 235a may be provided as a high-frequency power source for generating high-frequency power. The high-frequency power source may include a radio-frequency (RF) power source. The electrode plate 230 may receive high-frequency power from the third power source 235a through a third power line 235c. For example, the electrode plate 230 may receive RF power from the third power source 235a through the third power line 235c. The RF power may be RF bias power applied to the electrode plate 230 to control ion energy in the plasma. The electrode plate 230 may be electrically connected to or disconnected from the third power source 235a by turning on or off the switch 235b. When the substrate processing apparatus 10 is an etching apparatus, an etch rate may be controlled by controlling the ion energy in the plasma.

Furthermore, in some cases, the RF bias power may at least partially contribute to the generation and maintenance of the plasma. As such, the electrode plate 230 may function as an electrode.

The focus ring 240 may be disposed on an edge region of the dielectric plate 220. The focus ring 240 may have a ring shape and may be disposed along the circumference of the dielectric plate 220. A top surface of the focus ring 240 may be stepped in such a manner that an outer portion 240a is higher than an inner portion 240b thereof. The inner portion 240b of the top surface of the focus ring 240 may be positioned at the same height as the top surface of the dielectric plate 220. The inner portion 240b of the top surface of the focus ring 240 may support the edge region of the substrate W positioned outside the dielectric plate 220. The outer portion 240a of the focus ring 240 may be provided to surround the edge region of the substrate W. The outer portion 240a of the focus ring 240 may be at a higher level than the substrate W. In example embodiments, a sidewall between the inner portion 240b and the outer portion 240a may be perpendicular to both the inner portion 240b and the outer portion 240a. Although not illustrated, in other embodiments, a sidewall between the inner portion 240b and the outer portion 240a may be at an angle to both the inner portion 240b and the outer portion 240a. The focus ring 240 may control an electromagnetic field to generate the plasma at a uniform density over the entire region of the substrate W. As such, the plasma may be generated uniformly over the entire region of the substrate W and thus the substrate W may be uniformly etched.

The plasma unit 300 may include an RF power source 310, a wave guide 320, and antennas 330. The plasma unit 300 may excite a process gas in the process chamber 100 to a plasma state. The plasma unit 300 may use an ICP plasma source. When the ICP plasma source is used, the antennas 330 provided on the process chamber 100 and the electrode plate 230 provided in the process chamber 100 as a lower electrode may be included. The antennas 330 and the electrode plate 230 may be disposed parallel to each other in a horizontal direction across the processing space 101.

In addition to the electrode plate 230 which receives an RF signal from the third power source 235a, the antennas 330 may also receive an RF signal from an RF power source 310 to be supplied with energy for generating the plasma. An electric field may be generated in a space between the two electrodes, and a process gas supplied into the space may be excited to a plasma state. This plasma is used to process the substrate W. The RF signals applied to the antennas 330 and the electrode plate 230 may be controlled by a controller (not shown). According to an example embodiment, the wave guide 320 may be disposed above the antennas 330. The wave guide 320 transmits the RF signal from the RF power source 310 to the antennas 330. The wave guide 320 may have a conductor insertable into the wave guide 320.

Meanwhile, the example embodiments may be applied not only to the illustrated ICP processing apparatus but also to other plasma processing apparatuses. The other plasma processing apparatuses may include capacitively coupled plasma (CCP) processing apparatuses, plasma processing apparatuses using radial line slot antennas, helicon wave plasma (HWP) processing apparatuses, electron cyclotron resonance (ECR) plasma processing apparatuses, etc. For example, when the substrate processing apparatus 10 according to the example embodiments is a CCP processing apparatus, to generate the plasma, the RF signal from the RF power source 310 may be applied to a shower head in the process chamber 100 rather than to the antennas 330. However, in the CCP processing apparatus as well as the ICP processing apparatus, RF bias power may be commonly applied to the substrate support 200 to control ion energy in the plasma generated in the process chamber 100.

The gas supply unit 400 may supply a process gas into the process chamber 100. The gas supply unit 400 may include a gas supply nozzle 410, a gas supply line 420, and a gas reservoir 430. The gas supply nozzle 410 may be mounted at a central portion of the window 140 serving as a top surface of the process chamber 100. An injector may be provided on a bottom surface of the gas supply nozzle 410. The injection hole may supply the process gas into the process chamber 100. The gas supply line 420 may connect the gas supply nozzle 410 to the gas reservoir 430. The gas supply line 420 may supply, to the gas supply nozzle 410, the process gas stored in the gas reservoir 430. A valve 421 may be mounted on the gas supply line 420. The valve 421 may open or close the gas supply line 420 to control a flow rate of the process gas supplied through the gas supply line 420.

The process gas supplied by the gas supply unit 400 may include at least one of methane (CF₄), hydrogen (H₂), hydrogen bromide (HBr), nitrogen trifluoride (NF₃), difluoromethane (CH₂F₂), oxygen (O₂), fluorine (F₂), hydrogen fluoride (HF), and combinations thereof. Meanwhile, the process gas according to an example embodiment may be selected differently as needed. The process gas according to an example embodiment is excited to a plasma state to etch the substrate W.

The baffle unit 500 may be positioned between the inner wall of the process chamber 100 and the substrate support 200. The baffle unit 500 may include a baffle 510. The baffle 510 may be provided in a ring shape. A plurality of through holes may be provided in the baffle 510. The process gas provided into the process chamber 100 may pass through the through holes of the baffle 510 and be expelled through the vent holes 102. The flow of the process gas may be controlled according to the shape of the baffle 510 and the shape of the through holes.

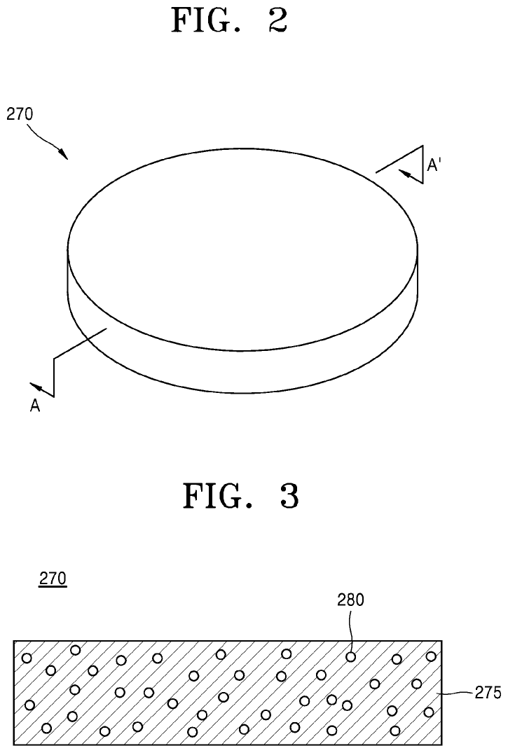

Referring to FIGS. 1 and 2, the substrate processing apparatus 10 according to an example embodiment includes the insulation plate 270 disposed under the substrate support 200. The insulation plate 270 is an element different from the above-described substrate support 200. The insulation plate 270 may be coupled to the electrode plate 230 of the substrate support 200 through, for example, bolts. The insulation plate 270 is a chamber insulation plate disposed under the substrate support 200 to electrically insulate the substrate support 200 from the process chamber 100. The insulation plate 270 may be disposed in contact with a bottom surface of the electrode plate 230 to reduce loss of the RF bias power applied to the electrode plate 230. The insulation plate 270 may have a circular shape, and may have a diameter the same as that of the electrode plate 230. The insulation plate 270 may be understood as a chamber insulation plate including a base material body made of a ceramic material having a first dielectric constant, and a dielectric constant controller dispersed in the base material body and having a second dielectric constant different from the first dielectric constant.

The material having the first dielectric constant may include at least one of, for example, aluminum nitride (AlN), silicon carbide (SiC), yttria (Y₂O₃), sapphire, yttrium oxyfluoride (YOF), and alumina (Al₂O₃). However, the above-mentioned materials are examples, and in other example embodiments, the base material body may include other materials for forming an insulator.

In general, permittivity may be understood as the ability of a dielectric substance to induce an electric charge. The dielectric substances may be polarized by an external electric field, and the degree of such polarization varies depending on a material even in the same electric field. A material constant for expressing this phenomenon is the permittivity, and the higher the permittivity is, the more the dielectric substance is polarized. A permittivity ε may be represented as a product of a vacuum permittivity ε₀ and a dielectric constant εᵣ that is a relative permittivity.

By adopting the insulation plate 270 having the above-described configuration, the loss of RF bias power may be reduced. For example, the insulation plate 270 is a non-conductor and thus may reduce the loss of RF bias power applied from the third power source 235a to the electrode plate 230.

The insulation plate 270 may contribute as a reactance component for an RF current applied to the electrode plate 230. A reactance X consists of an inductive reactance component ωL and a capacitive reactance component 1/(ωC). That is, X=ωL−1/(ωC).

When the dielectric constant εᵣ of the insulation plate 270 is increased, a capacitance C proportional to the dielectric constant εᵣ may also be increased, the reactance X for an RF current may be reduced, the loss of RF bias power may be increased, and thus an etch rate of an etching system may not be easily improved.

According to the example embodiments, by adopting the insulation plate 270 including a base material body made of a ceramic material having a first dielectric constant, and a dielectric constant controller dispersed in the base material body and having a second dielectric constant different from the first dielectric constant, the dielectric constant εᵣ of the insulation plate 270 may be reduced, the capacitance C proportional to the dielectric constant εᵣ may also be reduced, and the reactance X for an RF current may be increased, the loss of RF bias power applied to the electrode plate 230 may be reduced, and thus an etch rate of an etching system may be improved (see FIG. 16).

FIG. 16 shows, through a test, that a dry etch rate E/R is linearly increased in proportion to the reactance X of the insulation plate 270 in the substrate processing apparatus 10 for dry etching.

Meanwhile, a base plate 250 may be positioned at the bottom of the substrate support 200. A space 255 may be provided in the base plate 250. Although not shown in the drawings, according to an embodiment, the base plate 250 may have an open bottom. In addition, although not shown in the drawings, according to an embodiment, the base plate 250 may have an open top. The space 255 provided by the base plate 250 may allow air to flow to or from the outside of the space 255. An outer radius of the base plate 250 may be the same as the outer radius of the electrode plate 230. For example, a lift pin module (not shown) for moving the substrate W from an external transfer member onto the dielectric plate 220 may be positioned in the inner space 255 of the base plate 250. The base plate 250 may be made of a metal. The inner space 255 of the base plate 250 may be provided with air. Air has a lower permittivity than an insulator and thus may serve to reduce an electromagnetic field in the substrate support 200.

The base plate 250 may have a plurality of connecting members 253. The connecting members 253 may connect the outer surface of the base plate 250 and the inner wall of the process chamber 100. The connecting members 253 may be provided on the outer surface of the base plate 250 at regular intervals. The connecting members 253 may support the substrate support 200 inside the process chamber 100. In addition, the connecting members 253 may be connected to the inner wall of the process chamber 100 so that the base plate 250 is electrically grounded.

The first power line 223c connected to the first power source 223a, the second power line 225c connected to the second power source 225a, the third power line 235c connected to the third power source 235a, the heat transfer medium supply line 231b connected to the heat transfer medium reservoir 231a, and the coolant supply line 232c connected to the coolant reservoir 232a may extend into the base plate 250 through the inner space of one or more of the connecting members 253.

The above-described insulation plate 270 may be positioned between the dielectric plate 220 and the base plate 250. The insulation plate 270 may cover a top surface of the base plate 250. The insulation plate 270 may have a cross-sectional area corresponding to the electrode plate 230. The insulation plate 270 may serve to increase an electrical distance between the electrode plate 230 and the base plate 250.

Various embodiments of the insulation plate 270 as a chamber insulation plate capable of implementing the above-described technical features will now be described.

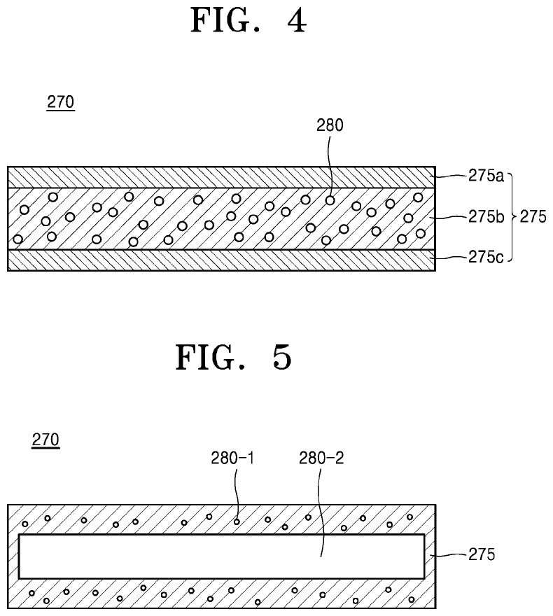

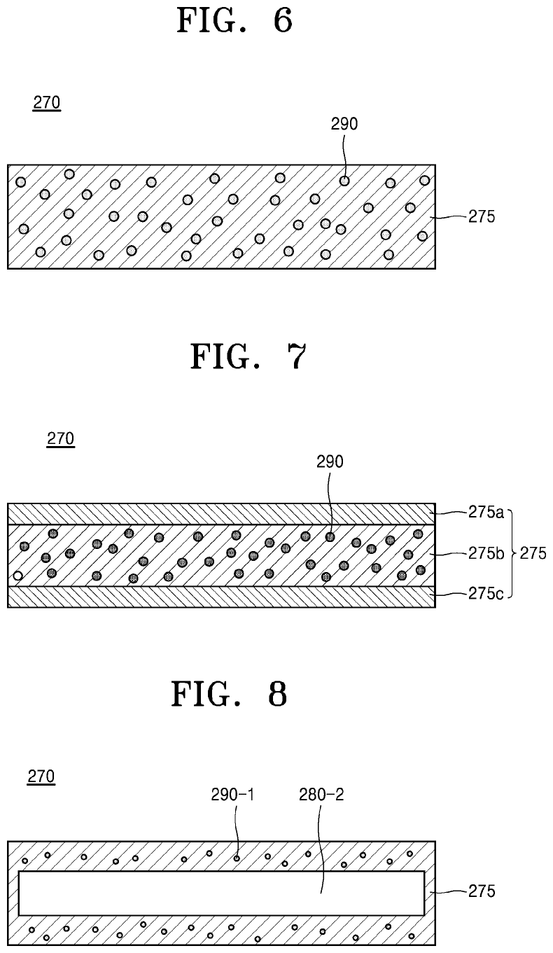

FIG. 2 is a perspective view of the insulation plate 270 of the substrate processing apparatus 10, according to example embodiments, and FIGS. 3 to 8 are cross-sectional views of the insulation plate 270 taken along line A-A′ of FIG. 2, according to various example embodiments.

Referring to FIGS. 1, 2, and 3, the insulation plate 270 according to a first example embodiment includes a base material body 275 made of a ceramic material having a first dielectric constant, and a dielectric constant controller dispersed in the base material body 275 and having a second dielectric constant different from the first dielectric constant, wherein the dielectric constant controller includes pores 280. In example embodiments, each of the pores 280 may be void of material, or may be pockets of gas, such as air or inert gases. The dielectric constant of the pores 280 may be about 1 (e.g., less than 1.05).

The material having the first dielectric constant to constitute the base material body 275 may include at least one of AlN, SiC, Y₂O₃, sapphire, YOF, and Al₂O₃.

The insulation plate 270 may have a porosity of, for example, 2% to 20%. The porosity may be understood as a ratio of a volume of the pores 280 to a total volume of the insulation plate 270.

When the porosity of the insulation plate 270 is less than 2%, the dielectric constant εᵣ of the insulation plate 270 may be increased, the capacitance C proportional to the dielectric constant εᵣ may also be increased, the reactance X for an RF current may be reduced, the loss of RF bias power may be increased, and thus an etch rate of an etching system may not be easily improved.

Meanwhile, when the porosity of the insulation plate 270 is greater than 20%, a mechanical strength of the porous insulation plate 270 may be reduced and thus a lifespan thereof may also be reduced.

However, the above-mentioned range of porosity is an example, and the porosity may not be limited thereto depending on material, shape, and use.

Referring to FIGS. 1, 2, and 4, the insulation plate 270 according to a second example embodiment includes a base material body 275 made of a ceramic material having a first dielectric constant, and a dielectric constant controller dispersed in the base material body 275 and having a second dielectric constant different from the first dielectric constant, wherein the dielectric constant controller includes pores 280.

The insulation plate 270 may have a laminated structure having different porosities, and a porosity in an upper layer 275a and a lower layer 275c of the insulation plate 270 may be different from the porosity in a middle layer 275b interposed between the upper and lower layers 275a and 275c. For example, the porosity in the middle layer 275b may be higher than the porosity in the upper and lower layers 275a and 275c. In this case, the upper and lower layers 275a and 275c may have a relatively low porosity and thus contribute to ensuring a mechanical strength of the insulation plate 270, and the middle layer 275b may have a relatively high porosity and thus contribute to reducing the dielectric constant εᵣ of the insulation plate 270, reducing the loss of RF bias power applied to the electrode plate 230, and improving an etch rate of an etching system.

Meanwhile, in the insulation plate 270 according to a modified second example embodiment, the porosity in the middle layer 275b may be lower than the porosity in the upper and lower layers 275a and 275c. In this case, the middle layer 275b may have a relatively low porosity and thus contribute to ensuring a mechanical strength of the insulation plate 270, and the upper and lower layers 275a and 275c may have a relatively high porosity and thus contribute to reducing the dielectric constant εᵣ of the insulation plate 270, reducing the loss of RF bias power applied to the electrode plate 230, and improving an etch rate of an etching system.

Referring to FIGS. 1, 2, and 5, the insulation plate 270 according to a third example embodiment includes a base material body 275 made of a ceramic material having a first dielectric constant, and a dielectric constant controller dispersed in the base material body 275 and having a second dielectric constant different from the first dielectric constant, wherein the dielectric constant controller includes pores.

The base material body 275 made of the ceramic material having the first dielectric constant forms an outer portion of the insulation plate 270, and a hollow 280-2 is provided in an inner portion of the insulation plate 270. The hollow 280-2 may be comprised of a plurality of pores 280 that have merged together. For example, one hollow 280-2 where pores are connected to each other without being dispersed and spaced apart from each other may be provided in the inner portion of the insulation plate 270. Furthermore, optionally, dispersed pores 280-1 may be provided in the base material body 275 made of the ceramic material having the first dielectric constant.

The outer portion of the insulation plate 270 made of the ceramic material having the first dielectric constant may contribute to ensuring a mechanical strength of the insulation plate 270, and the inner portion of the insulation plate 270 including one hollow 280-2 where pores are connected to each other without being dispersed may have a relatively high porosity and thus contribute to reducing the dielectric constant εᵣ of the insulation plate 270, reducing the loss of RF bias power applied to the electrode plate 230, and improving an etch rate of an etching system.

Referring to FIGS. 1, 2, and 6, the insulation plate 270 according to a fourth example embodiment includes a base material body 275 made of a ceramic material having a first dielectric constant, and a dielectric constant controller dispersed in the base material body 275 and having a second dielectric constant different from the first dielectric constant, wherein the dielectric constant controller includes particles 290 having a second dielectric constant lower than the first dielectric constant.

The material having the first dielectric constant to constitute the base material body 275 and the material having the second dielectric constant to constitute the particles 290 dispersed in the base material body 275 may be different materials, and each material may include at least one of AlN, SiC, Y₂O₃, sapphire, YOF, and Al₂O₃. For example, the material having the first dielectric constant to constitute the base material body 275 may include at least one of AlN, SiC, Y₂O₃, sapphire, YOF, and Al₂O₃, and the material having the second dielectric constant to constitute the particles 290 dispersed in the base material body 275 may include at least one of AlN, SiC, Y₂O₃, sapphire, YOF, and Al₂O₃ that has a dielectric constant lower than that of the first dielectric constant.

By adopting the insulation plate 270 according to the fourth example embodiment, the dielectric constant εᵣ of the insulation plate 270 may be reduced, the capacitance C proportional to the dielectric constant εᵣ may also be reduced, and the reactance X for an RF current may be increased, the loss of RF bias power applied to the electrode plate 230 may be reduced, and thus an etch rate of an etching system may be improved.

Meanwhile, unlike the insulation plate 270 according to the first embodiment described above in relation to FIG. 3, in the insulation plate 270 according to the fourth example embodiment, because the pores 280 are replaced with the particles 290 having the second dielectric constant, a mechanical strength of the insulation plate 270 may be ensured more easily.

Referring to FIGS. 1, 2, and 7, the insulation plate 270 according to a fifth example embodiment includes a base material body 275 made of a ceramic material having a first dielectric constant, and a dielectric constant controller dispersed in the base material body 275 and having a second dielectric constant different from the first dielectric constant, wherein the dielectric constant controller includes particles 290 having a second dielectric constant lower than the first dielectric constant.

The material having the first dielectric constant to constitute the base material body 275 and the material having the second dielectric constant to constitute the particles 290 dispersed in the base material body 275 may be different materials, and each material may include at least one of AlN, SiC, Y₂O₃, sapphire, YOF, and Al₂O₃.

The insulation plate 270 may have a laminated structure having different dispersion densities of the particles 290 having the second dielectric constant, and a dispersion density of the particles 290 having the second dielectric constant in an upper layer 275a and a lower layer 275c of the insulation plate 270 may be different from the dispersion density of the particles 290 having the second dielectric constant in a middle layer 275b interposed between the upper and lower layers 275a and 275c. For example, the dispersion density in the middle layer 275b may be higher than the dispersion density in the upper and lower layers 275a and 275c. In this case, the middle layer 275b may have a relatively high dispersion density and thus contribute to reducing the dielectric constant εᵣ of the insulation plate 270, reducing the loss of RF bias power applied to the electrode plate 230, and improving an etch rate of an etching system.

Referring to FIGS. 1, 2, and 8, the insulation plate 270 according to a sixth example embodiment includes a base material body 275 made of a ceramic material having a first dielectric constant, and a dielectric constant controller dispersed in the base material body 275 and having a second dielectric constant different from the first dielectric constant, wherein the dielectric constant controller includes particles 290-1 having a second dielectric constant lower than the first dielectric constant.

The material having the first dielectric constant to constitute the base material body 275 and the material having the second dielectric constant to constitute the particles 290-1 dispersed in the base material body 275 may be different materials, and each material may include at least one of AlN, SiC, Y₂O₃, sapphire, YOF, and Al₂O₃.

An outer portion of the insulation plate 270 made of the ceramic material having the first dielectric constant may contribute to ensuring a mechanical strength of the insulation plate 270, and an inner portion of the insulation plate 270 including one hollow 280-2 where pores are connected to each other without being dispersed may have a relatively high porosity and thus contribute to reducing the dielectric constant εᵣ of the insulation plate 270, reducing the loss of RF bias power applied to the electrode plate 230, and improving an etch rate of an etching system.

Furthermore, the particles 290-1 having the second dielectric constant lower than the first dielectric constant may be dispersed in the base material body 275 made of the ceramic material having the first dielectric constant.

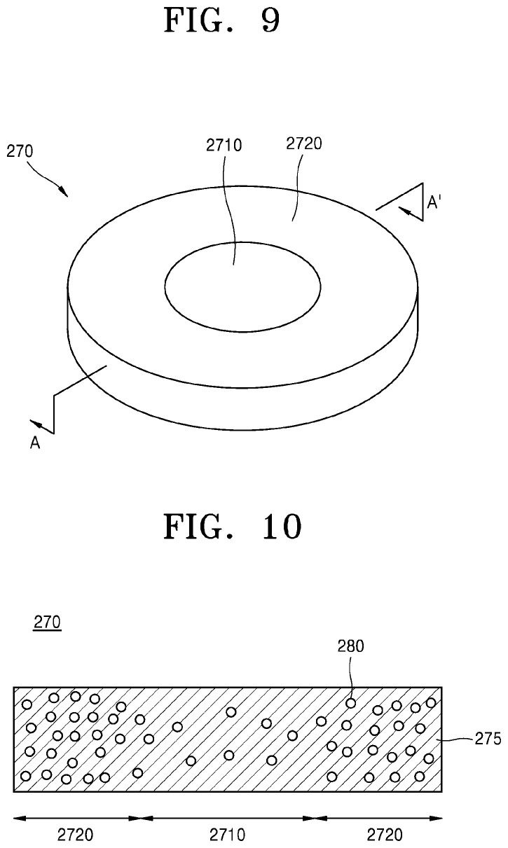

FIG. 9 is a perspective view of the insulation plate 270 of the substrate processing apparatus 10, according to other example embodiments, and FIGS. 10 to 15 are cross-sectional views of the insulation plate 270 taken along line A-A′ of FIG. 9, according to various example embodiments.

Referring to FIGS. 1, 9, and 10, the insulation plate 270 according to a seventh example embodiment includes a base material body 275 made of a ceramic material having a first dielectric constant, and a dielectric constant controller dispersed in the base material body 275 and having a second dielectric constant different from the first dielectric constant, wherein the dielectric constant controller includes pores 280.

A porosity in a central region 2710 of the insulation plate 270 corresponding to a central portion of the substrate W may be different from the porosity in an edge region 2720 of the insulation plate 270 corresponding to an edge portion of the substrate W. For example, the porosity in the central region 2710 of the insulation plate 270 may be lower than the porosity in the edge region 2720 of the insulation plate 270.

When it is assumed that non-uniform etching occurs due to a high etch rate at the central portion of the substrate W and a low etch rate at the edge portion of the substrate W under general process conditions, the non-uniformity may be solved by applying the insulation plate 270 having a lower porosity in the central region 2710 than in the edge region 2720. For example, because the porosity in the edge region 2720 is higher than that in the central region 2710, the dielectric constant εᵣ of the insulation plate 270 is reduced more significantly in the edge region 2720 than in the central region 2710, and thus the etch rate is increased more significantly in the edge region 2720 than in the central region 2710. Accordingly, by adopting the configuration of the insulation plate 270 shown in FIG. 10, the existing problem of the non-uniform etch rate may be solved and, ultimately, substrate etch uniformity may be improved.

Referring to FIGS. 1, 9, and 11, the insulation plate 270 according to an eighth example embodiment includes a base material body 275 made of a ceramic material having a first dielectric constant, and a dielectric constant controller dispersed in the base material body 275 and having a second dielectric constant different from the first dielectric constant, wherein the dielectric constant controller includes pores 280.

A porosity in a central region 2710 of the insulation plate 270 corresponding to a central portion of the substrate W may be different from the porosity in an edge region 2720 of the insulation plate 270 corresponding to an edge portion of the substrate W. For example, the porosity in the central region 2710 of the insulation plate 270 may be higher than the porosity in the edge region 2720 of the insulation plate 270.

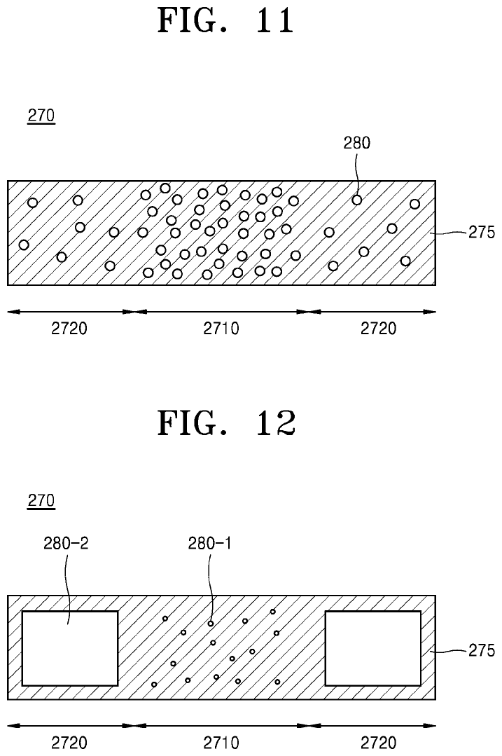

When it is assumed that non-uniform etching occurs due to a low etch rate at the central portion of the substrate W and a high etch rate at the edge portion of the substrate W under general process conditions, the non-uniformity may be solved by applying the insulation plate 270 having a higher porosity in the central region 2710 than in the edge region 2720. For example, because the porosity in the edge region 2720 is lower than that in the central region 2710, the dielectric constant εᵣ of the insulation plate 270 is reduced more significantly in the central region 2710 than in the edge region 2720, and thus the etch rate is increased more significantly in the central region 2710 than in the edge region 2720. Accordingly, by adopting the configuration of the insulation plate 270 shown in FIG. 11, the existing problem of the non-uniform etch rate may be solved and, ultimately, substrate etch uniformity may be improved.

Referring to FIGS. 1, 9, and 12, the insulation plate 270 according to a ninth example embodiment includes a base material body 275 made of a ceramic material having a first dielectric constant, and a dielectric constant controller dispersed in the base material body 275 and having a second dielectric constant different from the first dielectric constant, wherein the dielectric constant controller includes pores.

A porosity in a central region 2710 of the insulation plate 270 corresponding to a central portion of the substrate W may be different from the porosity in an edge region 2720 of the insulation plate 270 corresponding to an edge portion of the substrate W. For example, the porosity in the central region 2710 of the insulation plate 270 may be lower than the porosity in the edge region 2720 of the insulation plate 270. A hollow 280-2 may be provided in a ring shape in the edge region 2720 of the insulation plate 270. One ring-shaped hollow 280-2 where pores are connected to each other without being dispersed and spaced apart from each other may be provided in the edge region 2720 of the insulation plate 270. Furthermore, optionally, dispersed pores 280-1 may be provided in the central region 2710 of the insulation plate 270.

When it is assumed that non-uniform etching occurs due to a high etch rate at the central portion of the substrate W and a low etch rate at the edge portion of the substrate W under general process conditions, the non-uniformity may be solved by applying the insulation plate 270 having a lower porosity in the central region 2710 than in the edge region 2720. For example, because the porosity in the edge region 2720 is higher than that in the central region 2710, the dielectric constant εᵣ of the insulation plate 270 is reduced more significantly in the edge region 2720 than in the central region 2710, and thus the etch rate is increased more significantly in the edge region 2720 than in the central region 2710. Accordingly, by adopting the configuration of the insulation plate 270 shown in FIG. 12, the existing problem of the non-uniform etch rate may be solved and, ultimately, substrate etch uniformity may be improved.

Referring to FIGS. 1, 9, and 13, the insulation plate 270 according to a tenth example embodiment includes a base material body 275 made of a ceramic material having a first dielectric constant, and a dielectric constant controller dispersed in the base material body 275 and having a second dielectric constant different from the first dielectric constant, wherein the dielectric constant controller includes pores.

A porosity in a central region 2710 of the insulation plate 270 corresponding to a central portion of the substrate W may be different from the porosity in an edge region 2720 of the insulation plate 270 corresponding to an edge portion of the substrate W. For example, the porosity in the central region 2710 of the insulation plate 270 may be higher than the porosity in the edge region 2720 of the insulation plate 270. A hollow 280-2 may be provided in the central region 2710 of the insulation plate 270. One hollow 280-2 where pores are connected to each other without being dispersed and spaced apart from each other may be provided in the central region 2710 of the insulation plate 270. Furthermore, optionally, dispersed pores 280-1 may be provided in the edge region 2720 of the insulation plate 270.

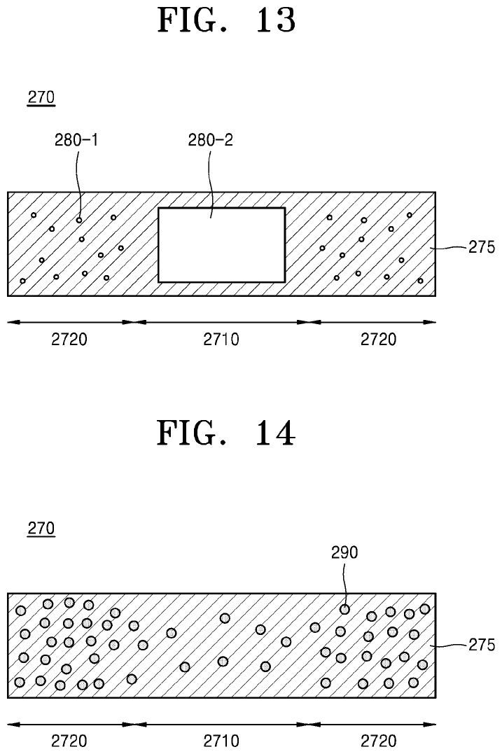

When it is assumed that non-uniform etching occurs due to a low etch rate at the central portion of the substrate W and a high etch rate at the edge portion of the substrate W under general process conditions, the non-uniformity may be solved by applying the insulation plate 270 having a higher porosity in the central region 2710 than in the edge region 2720. For example, because the porosity in the edge region 2720 is lower than that in the central region 2710, the dielectric constant εᵣ of the insulation plate 270 is reduced more significantly in the central region 2710 than in the edge region 2720, and thus the etch rate is reduced more significantly in the edge region 2720 than in the central region 2710. Accordingly, by adopting the configuration of the insulation plate 270 shown in FIG. 13, the existing problem of the non-uniform etch rate may be solved and, ultimately, substrate etch uniformity may be improved.

Referring to FIGS. 1, 9, and 14, the insulation plate 270 according to an eleventh example embodiment includes a base material body 275 made of a ceramic material having a first dielectric constant, and a dielectric constant controller dispersed in the base material body 275 and having a second dielectric constant different from the first dielectric constant, wherein the dielectric constant controller includes particles 290 having a second dielectric constant lower than the first dielectric constant.

The material having the first dielectric constant to constitute the base material body 275 and the material having the second dielectric constant to constitute the particles 290 dispersed in the base material body 275 may be different materials, and each material may include at least one of AlN, SiC, Y₂O₃, sapphire, YOF, and Al₂O₃.

A dispersion density of the particles 290 in a central region 2710 of the insulation plate 270 corresponding to a central portion of the substrate W may be different from the dispersion density of the particles 290 in an edge region 2720 of the insulation plate 270 corresponding to an edge portion of the substrate W. For example, the dispersion density of the particles 290 in the central region 2710 of the insulation plate 270 may be lower than the dispersion density of the particles 290 in the edge region 2720 of the insulation plate 270.

When it is assumed that non-uniform etching occurs due to a high etch rate at the central portion of the substrate W and a low etch rate at the edge portion of the substrate W under general process conditions, the non-uniformity may be solved by applying the insulation plate 270 having a lower dispersion density of the particles 290 in the central region 2710 than in the edge region 2720. For example, because the dispersion density of the particles 290 in the edge region 2720 is higher than that in the central region 2710, the dielectric constant εᵣ of the insulation plate 270 is reduced more significantly in the edge region 2720 than in the central region 2710, and thus the etch rate is increased more significantly in the edge region 2720 than in the central region 2710. Accordingly, by adopting the configuration of the insulation plate 270 shown in FIG. 14, the existing problem of the non-uniform etch rate may be solved and, ultimately, substrate etch uniformity may be improved.

Referring to FIGS. 1, 9, and 15, the insulation plate 270 according to a twelfth example embodiment includes a base material body 275 made of a ceramic material having a first dielectric constant, and a dielectric constant controller dispersed in the base material body 275 and having a second dielectric constant different from the first dielectric constant, wherein the dielectric constant controller includes particles 290 having a second dielectric constant lower than the first dielectric constant.

The material having the first dielectric constant to constitute the base material body 275 and the material having the second dielectric constant to constitute the particles 290 dispersed in the base material body 275 may be different materials, and each material may include at least one of AlN, SiC, Y₂O₃, sapphire, YOF, and Al₂O₃.

A dispersion density of the particles 290 in a central region 2710 of the insulation plate 270 corresponding to a central portion of the substrate W may be different from the dispersion density of the particles 290 in an edge region 2720 of the insulation plate 270 corresponding to an edge portion of the substrate W. For example, the dispersion density of the particles 290 in the central region 2710 of the insulation plate 270 may be higher than the dispersion density of the particles 290 in the edge region 2720 of the insulation plate 270.

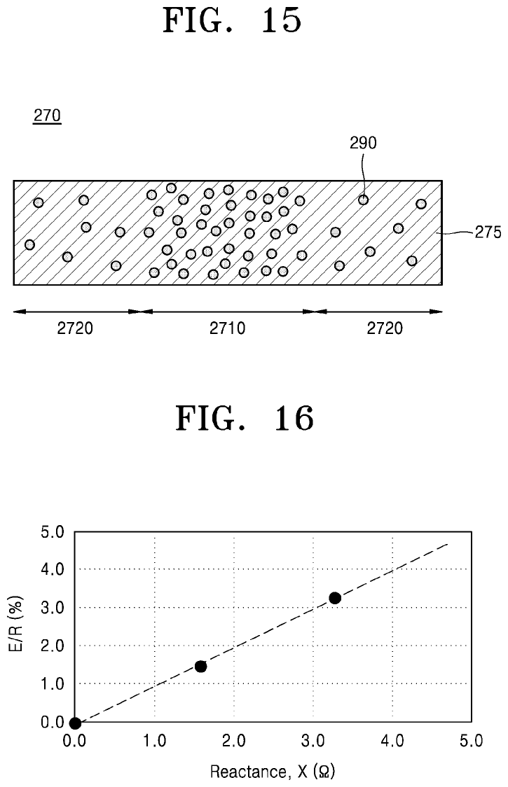

When it is assumed that non-uniform etching occurs due to a low etch rate at the central portion of the substrate W and a high etch rate at the edge portion of the substrate W under general process conditions, the non-uniformity may be solved by applying the insulation plate 270 having a higher dispersion density of the particles 290 in the central region 2710 than in the edge region 2720. For example, because the dispersion density of the particles 290 in the edge region 2720 is lower than that in the central region 2710, the dielectric constant εᵣ of the insulation plate 270 is reduced more significantly in the central region 2710 than in the edge region 2720, and thus the etch rate is increased more significantly in the central region 2710 than in the edge region 2720. Accordingly, by adopting the configuration of the insulation plate 270 shown in FIG. 15, the existing problem of the non-uniform etch rate may be solved and, ultimately, substrate etch uniformity may be improved.

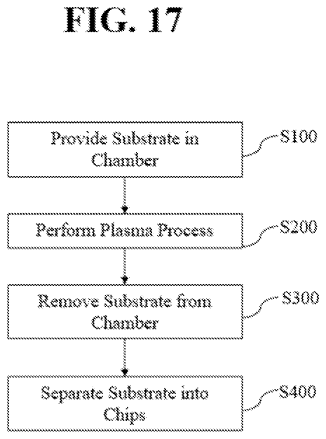

FIG. 17 is a flow chart illustrating a method of manufacturing a semiconductor device according to an example embodiment. Regarding FIG. 17, the manufacturing method includes steps of providing a semiconductor substrate in a plasma chamber (S100), performing a plasma process on the semiconductor substrate (S200), removing the semiconductor substrate from the plasma chamber (S300), and separating the semiconductor substrate into a plurality of chips (S400). For example, the plasma process may include an etching process, an ashing process, a deposition process, a sputtering process and/or a cleaning process. For example, during the plasma process, a dielectric layer or a conductor layer may be etched. For example, the dielectric layer or the conductor layer may be patterned by the plasma while a mask layer covers a portion of the dielectric layer or the conductor layer. For example, the mask layer may be formed by a photolithography process, e.g., a double patterning process or a quadruple patterning process.

The plasma chamber may be a process chamber 100 of a substrate processing apparatus 10 described in the previous embodiments of the current disclosure. The plasma chamber may include various features described with reference to FIGS. 1 through 16. The semiconductor substrate may be a bare substrate on which a semiconductor circuit may be formed in later steps of processes. Alternatively, the semiconductor substrate may be a substrate on which a semiconductor circuit is already formed. After removing the semiconductor substrate from the chamber and/or performing additional processes completing semiconductor circuits on the semiconductor substrate, the semiconductor substrate may be divided into a plurality of semiconductor chips as shown in step S400 of FIG. 17. The semiconductor substrate may be the substrate W described with reference to FIG. 1. For example, the semiconductor chips may be packaged to form semiconductor devices.

A chamber insulation plate capable of implementing an etching process having a high etch rate and of improving etch uniformity on a substrate, and a substrate processing apparatus including the same, according to various example embodiments, have been described above.

According to the afore-described example embodiments, a chamber insulation plate capable of implementing an etching process having a high etch rate and of improving etch uniformity on a substrate, and a substrate processing apparatus including the same may be provided. However, the scope of the present invention is not limited to the above effects.

The effects of the present invention are not limited to the above-described effects, and additional effects will be apparent to one of ordinary skill in the art from the above descriptions and the attached drawings.

While the present invention has been particularly shown and described with reference to embodiments thereof, it will be understood by one of ordinary skill in the art that various changes in form and details may be made therein. For example, it will be understood that a porosity or a dispersion density of particles in an insulation plate may vary in a gradual manner as well as in a stepwise manner between layers.

Therefore, the scope of the invention is defined by the following claims.

What is claimed is:

1. A chamber insulation plate to be disposed under a substrate support for supporting a substrate in a plasma processing chamber, the chamber insulating part configured to electrically insulate the substrate support from the chamber, the chamber insulation plate comprising:
a base material body made of a ceramic material having a first dielectric constant; and
a dielectric constant controller dispersed in the base material body and having a second dielectric constant different from the first dielectric constant to reduce loss of radio-frequency (RF) bias power applied to the substrate support to control ion energy in the plasma.

2. The chamber insulation plate of claim 1, wherein the dielectric constant controller comprises pores.

3. The chamber insulation plate of claim 2, wherein the chamber insulation plate has a porosity of 2% to 20%.

4. The chamber insulation plate of claim 1, wherein the ceramic material having the first dielectric constant comprises at least one of aluminum nitride (AlN), silicon carbide (SiC), yttria (Y₂O₃), sapphire, yttrium oxyfluoride (YOF), and alumina (Al₂O₃).

5. The chamber insulation plate of claim 1,
wherein the dielectric constant controller comprises particles having the second dielectric constant, and
wherein the second dielectric constant is lower than the first dielectric constant.

6. A substrate processing apparatus comprising:
a chamber having a processing space for processing a substrate with plasma;
a substrate support for supporting the substrate in the chamber; and
an insulation plate disposed under the substrate support to electrically insulate the substrate support from the chamber,
wherein the insulation plate comprises:
a base material body made of a ceramic material having a first dielectric constant; and
a dielectric constant controller dispersed in the base material body and having a second dielectric constant lower than the first dielectric constant to reduce loss of radio-frequency (RF) bias power applied to the substrate support to control ion energy in the plasma.

7. The substrate processing apparatus of claim 6,
wherein the substrate support comprises a dielectric plate for placing the substrate thereon, and an electrode plate disposed under the dielectric plate, and
wherein the insulation plate is disposed in contact with a bottom surface of the electrode plate to reduce loss of the RF bias power applied to the electrode plate.

8. The substrate processing apparatus of claim 6, wherein the ceramic material having the first dielectric constant comprises at least one of aluminum nitride (AlN), silicon carbide (SiC), yttria (Y₂O₃), sapphire, yttrium oxyfluoride (YOF), and alumina (Al₂O₃).

9. The substrate processing apparatus of claim 6, wherein the dielectric constant controller having the second dielectric constant comprises pores.

10. The substrate processing apparatus of claim 9, wherein a porosity in a central region of the insulation plate corresponding to a central portion of the substrate is different from a porosity in an edge region of the insulation plate corresponding to an edge portion of the substrate.

11. The substrate processing apparatus of claim 10, wherein the porosity in the central region of the insulation plate is lower than the porosity in the edge region of the insulation plate.

12. The substrate processing apparatus of claim 10, wherein the porosity in the central region of the insulation plate is higher than the porosity in the edge region of the insulation plate.

13. The substrate processing apparatus of claim 9,
wherein the insulation plate has a laminated structure having different porosities, and
wherein a porosity in an upper layer and a lower layer of the insulation plate is different from a porosity in a middle layer interposed between the upper and lower layers.

14. The substrate processing apparatus of claim 13, wherein the porosity in the upper and lower layers is lower than the porosity in the middle layer.

15. The substrate processing apparatus of claim 13, wherein the porosity in the upper and lower layers is higher than the porosity in the middle layer.

16. The substrate processing apparatus of claim 6,
wherein the dielectric constant controller having the second dielectric constant comprises particles having the second dielectric constant.

17. The substrate processing apparatus of claim 16, wherein the particles having the second dielectric constant comprise at least one of aluminum nitride (AlN), silicon carbide (SiC), yttria (Y₂O₃), sapphire, yttrium oxyfluoride (YOF), and alumina (Al₂O₃).

18. The substrate processing apparatus of claim 16,
wherein the insulation plate comprises a central region corresponding to a central portion of the substrate, and an edge region corresponding to an edge portion of the substrate, and
wherein a dispersion density of the particles having the second dielectric constant in the central region is different from a dispersion density of the particles having the second dielectric constant in the edge region.

19. The substrate processing apparatus of claim 16,
wherein the insulation plate has a laminated structure having different dispersion densities of the particles having the second dielectric constant, and
wherein a dispersion density of the particles having the second dielectric constant in an upper layer and a lower layer of the insulation plate is different from a dispersion density of the particles having the second dielectric constant in a middle layer interposed between the upper and lower layers.

20. A substrate processing apparatus comprising:
a chamber having a processing space for processing a substrate with plasma;
a substrate support for supporting the substrate in the chamber; and
an insulation plate disposed under the substrate support to electrically insulate the substrate support from the chamber,
wherein the insulation plate comprises:
a base material body made of a ceramic material having a first dielectric constant; and
pores dispersed in the base material body to reduce the dielectric constant of the insulation plate,
wherein the ceramic material having the first dielectric constant comprises at least one of aluminum nitride (AlN), silicon carbide (SiC), yttria (Y₂O₃), sapphire, yttrium oxyfluoride (YOF), and alumina (Al₂O₃), and
wherein the insulation plate has a porosity of 2% to 20%.
